(19) United States
(12) Patent Application Publication
(10) Pub. No.: US 2015/0084659 A1
(43) Pub. Date: Mar. 26, 2015

(54) CONTACT ARRANGEMENTS AND METHODS FOR DETECTING INCORRECT MECHANICAL CONTACTING OF CONTACT STRUCTURES

(71) Applicant: Infineon Technologies AG, Neubiberg (DE)

(72) Inventors: Wolfgang Horn, Klagenfurt a. W. (AT); Mario Wiesner, Klagenfurt a. W. (AT)

(73) Assignee: Infineon Technologies AG, Neubiberg (DE)

(21) Appl. No.: 14/032,257

(22) Filed: Sep. 20, 2013

(51) Int. Cl. G01R 31/28; G01R 1/067

(52) U.S. Cl. CPC G01R 31/2889; G01R 1/06794
USPC 324/754.1; 324/755.01

(57) ABSTRACT

A contact arrangement is provided, including a contact structure and a sense structure. The sense structure may be arranged in proximity of the contact structure. The sense structure may be configured such that a correct mechanical contacting of the contact structure will not impact the sense structure and an incorrect mechanical contacting of the contact structure will impact the sense structure.

### TECHNICAL FIELD

Various embodiments relate generally to contact arrangements and methods for detecting incorrect mechanical contacting of a contact structure.

### BACKGROUND

Electrical devices, for example electrical circuits and semiconductors, may need to be contacted electrically, for example during production tests and during operation. The electrical contact may for example be achieved by using contact pins, cantilever probes, vertical probes, ball bonds, wedge bonds, ball contacts, and any other suitable contacting technologies.

Usually, a mechanical contacting of the electrical device is required in order to produce the electrical connection. However, the mechanical contacting may be prone to errors, for example due to mechanical tolerances, misalignment, deformation or too high a contact force. For example, a cantilever probe may hit an edge of a contact area and may damage neighboring structures. As another example, a misaligned wire bond may cause a failure later on during operating life even though it passes functional tests.

An incorrect mechanical contacting that it is not detected during functional tests or parametric production tests may present a potential reliability risk. However, automotive systems may require low reliability risks. For safety critical applications, conformance to ISO 26262 standard may be required.

### SUMMARY

A contact arrangement is provided, including a contact structure and a sense structure. The sense structure may be arranged in proximity of the contact structure. The sense structure may be configured such that a correct mechanical contacting of the contact structure will not impact the sense structure and an incorrect mechanical contacting of the contact structure will impact the sense structure.

### BRIEF DESCRIPTION OF THE DRAWINGS

In the drawings, like reference characters generally refer to the same parts throughout the different views. The drawings are not necessarily to scale, emphasis is instead generally being placed upon illustrating the principles of the invention. In the drawings, the left-most digit(s) of a reference number can identify the drawing in which the reference number first appears. The same numbers can be used throughout the drawings to reference like features and components. In the following description, various embodiments of the invention are described with reference to the following drawings, in which:

FIG. 1 shows an embodiment of a contact arrangement;

FIG. 2 shows another embodiment of a contact arrangement;

FIG. 3 shows still another embodiment of a contact arrangement;

FIG. 4 shows a further embodiment of a contact arrangement;

FIG. 5 shows still a further embodiment of a contact arrangement;

FIG. 6 shows yet another embodiment of a contact arrangement;

FIG. 7 shows an embodiment of a method; and

FIG. 8 shows another embodiment of a method.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

Some features of an embodiment may be isolated from other features of the embodiment, even if they are described together. Different embodiments are shown, however features from one embodiment may also be used in other embodiments.

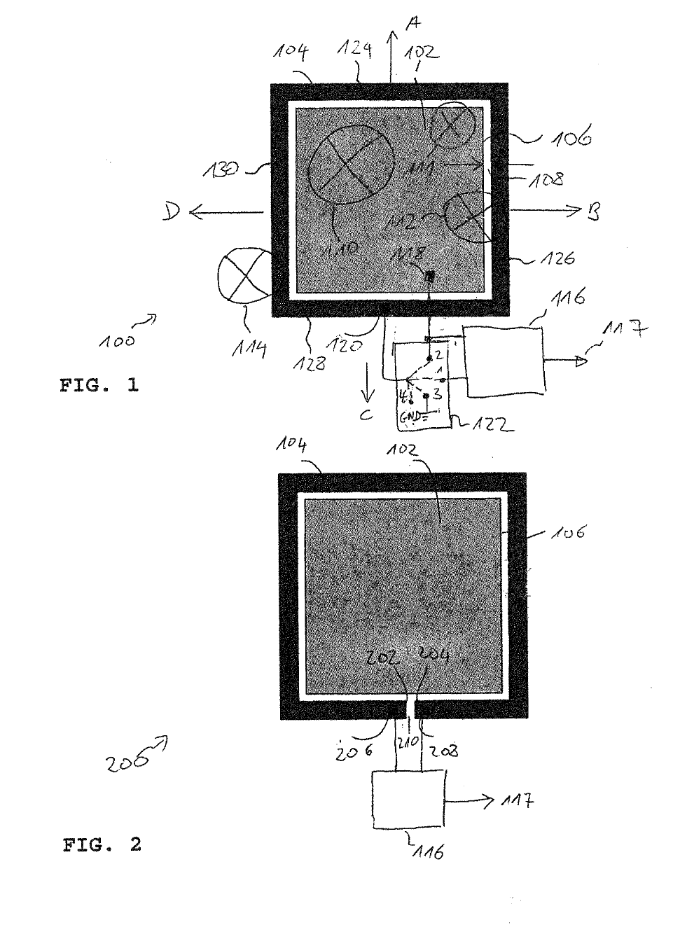

FIG. 1 shows an embodiment of a contact arrangement 100. In various embodiments, the contact arrangement 100 may include a contact structure 102 and a sense structure 104.

The contact structure 102 may be mechanically contacted by a contacting part. In various embodiments, the mechanical contacting may be temporary, for example when using a probe for testing purposes or in the case of electrical connectors. In various embodiments, the mechanical contacting may be permanent, for example in wire bonding or whenever a permanent electrical connection is formed.

In various embodiments, the contact structure 102 may be a contact area, such as a bond pad, for example of a semiconductor. However, the contact structure 102 is not limited to bond pads. The contact structure 102 may for example be part of an electrical connector, such as a plug or a socket. In various embodiments, the contact structure 102 may be electrically conducting.

In various embodiments, the sense structure 104 may be arranged in proximity of the contact structure 102. For example, the sense structure 104 may be arranged at a certain distance 108 from a border 106 of the contact structure 102. In various embodiments, the distance 108 may be chosen to be smaller than the contacting part used for mechanical contacting the contact structure 102. For example, if wire bonding is used for mechanical contacting, the wire ball may represent the contacting part and the distance 108 may be chosen to be smaller than the diameter of the wire ball. For example, if a probe is used for the mechanical contacting, the probe may represent the contacting part and the distance 108 may be chosen to be smaller than the contacting portion of the probe. In this way, a misalignment of the contacting part used for mechanical contacting the contact structure 102 may be detected since it may be in contact with both the contact structure 102 and the sense structure 104. In various embodiments, the sense structure 104 may include at least one electronically conducting portion arranged in proximity of a border of the contact structure. In various embodiments, the sense structure 104 may be a closed loop surrounding the contact structure 102.

In various embodiments, the sense structure 104 may be configured such that a correct mechanical contacting of the contact structure 102 will not impact the sense structure 104. In various embodiments, the wording “impact” may mean “to have an effect on”, “to influence”, “to interact with”, “to act on”, “to affect”, etc. For example, the sense structure 104 may be impacted by mechanical contacting, for example, by a wire bond or a probe. In various embodiments, the impact may include the electrical connecting of the contacting part and the sense structure 104. In various embodiments, the impact may for example occur when the contact force of the mechanical contacting exceeds an allowed limit or threshold which may cause damage to at least one of the contact structure 102, the sense structure 104 and their surroundings. An impact may also occur, for example, when the contacting part damages, for example by scratching, at least one of the contact structure 102, the sense structure 104 and their surroundings, for example due to misalignment of the contacting part.

In various embodiments, a correct mechanical contacting of the contact structure 102 may involve an alignment of the mechanical contacting, for example with respect to the contact structure 102 or other structures. In various embodiments, a correct mechanical contacting may be a mechanical contacting that is limited to or confined to the contact structure 102. For example, the mechanical contacting 110 in FIG. 1, which may, for example, be a wire bond such as a ball bond or a wedge bond, or a probe contact, is limited to or confined to the contact structure 102. In various embodiments, a correct mechanical contacting may be a mechanical contacting that does not involve a contact with the sense structure 104. For example, the mechanical contacting 111 in FIG. 1, which may, for example, be a wire bond such as a ball bond or a wedge bond, or a probe contact, is not confined to the contact structure 102; however, it is not in contact with the sense structure 104. The mechanical connections 110 and 111 may be considered as correct mechanical contacting as they do not impact the sense structure 104.

In various embodiments, a correct mechanical contacting of the contact structure 102 may involve a contact force, that is a force with which a contacting part is pressed onto the contact arrangement 100, that does not have an impact on some or all parts of the contact arrangement 100, for example on the sense structure 104. In this case, the contact structure 102, the sense structure 104 or a substrate on which the contact structure 102 and the sense structure 104 are arranged on will not be damaged.

In various embodiments, the sense structure 104 may be configured such that an incorrect mechanical contacting of the contact structure 102 will impact the sense structure 104. For example, an incorrect positioning or a misalignment or too high a contact force of the conducting part used for mechanically contacting the contact structure 102 may have an impact on the sense structure 104. In this case the impact may be a damage of the sense structure 104 for example by scratching it or providing an electrical connection to it. For example, the mechanical connection 112 shown in FIG. 1 may provide an electrical connection to the sense structure 104 thus having an impact on it.

The mechanical contacting 114 shown in FIG. 1 may also be considered as an incorrect mechanical contacting since it impacts the sense structure 104. It may be difficult for the sensing circuit 116, which will be described later, to detect the impact since the mechanical contacting is only in contact with the sense structure 104 and not with the contact structure 102. However, if the mechanical contacting 114 is necessary for the operation of a circuit arrangement, the incorrect mechanical contacting 114 may be detected during testing.

In various embodiments, the contact structure 102 and sense structure 104 may be respectively formed in one of or in more than one of a metal layer, an electrically conducting polysilicon layer and an electrically conducting diffusion region. In various embodiments, the contact structure 102 and the sense structure 104 may be arranged on a semiconductor substrate or a printed circuit board (PCB). The metal layer may for example be a top metal layer of a semiconductor.

In various embodiments, the contact structure 102 and the sense structure 104 may be arranged in the same conducting layer. In various embodiments, the contact structure 102 may be arranged in the same conducting plane as the closed loop 104. In various embodiments, the contact structure 102 and the sense structure 104 may include the same kind of surface. For example, they may consist of the same material and they may be produced during the same process. The material may for example be Aluminum. In various embodiments, the sense structure 104 doesn't have a passivation if it is arranged on a semiconductor and doesn't have a solder stop if it is arranged on a printed circuit board (PCB). If the mechanical contacting involves a bonding process, the bond ball or the bond wedge may be connected in like manner, that is with the same bonding quality and properties, to the contact structure 102 and the sense structure 104.

In various embodiments, the contact arrangement 100 may further include a sensing or detector circuit 116. In various embodiments, the sensing circuit 116 may be coupled to at least the sense structure 104, for example, the closed loop 104. In various embodiments, the sensing circuit 116 may be configured to detect the impact on the sense structure 104. For example, the sensing circuit 116 may detect a potential of the sense structure 104. The potential of the sense structure 104 may depend on whether there has been an incorrect mechanical contacting or a correct mechanical contacting. For example, the incorrect mechanical contacting 112 shown in FIG. 1 may cause the sense structure 104 to have the same potential as the contact structure 102, whereas the correct mechanical contacting 110 will not affect the potential of the sense structure 104.

The contact structure 102 may also be coupled to the sensing circuit 116. In various embodiments, the sensing circuit 116 is configured to determine at least one of an electrical resistance, an electrical current, and an electrical voltage (or potential difference) between the sense structure 104 and the contact structure 102. The sensing circuit 116 may then provide a corresponding signal at its output 117 which may be used to determine if a correct or an incorrect mechanical contacting has taken place and may for example be used for detecting a potential or latent reliability issue. For example, the incorrect mechanical contacting 112 shown in FIG. 1 may allow current to leak between the sense structure 104 and the contact structure 102, whereas the correct mechanical contacting 110 will not allow current to leak between the sense structure 104 and the contact structure 102. In various embodiments, the leakage current may be measured by applying a first potential to the sense structure 104 and a second potential to the contact structure 102 and then measuring the current.

In various embodiments, the signal at the output 117 may for example indicate a zero current value if no leakage current flows between the sense structure 104 and the contact structure 102. In various embodiments, suitable limits or thresholds may be set which the current value must exceed before a signal is output at the output 117, for example to indicate excessive leakage currents caused by mechanical damage.

In various embodiments, the signal at the output 117 may for example indicate a zero voltage value if there is no potential difference between the sense structure 104 and the contact structure 102. In various embodiments, suitable limits or thresholds may be set below which the voltage value must be before a signal is output at the output 117. For example, the limit or threshold may correspond to the amount of overlap of the contacting part with the contact structure 102 and the sense structure 104.

In various embodiments, the signal at the output 117 may for example indicate a zero resistance value if there is no resistance between the sense structure 104 and the contact structure 102. In various embodiments, suitable limits or thresholds may be set below which the resistance value must be before a signal is output at the output 117. For example, the limit or threshold may correspond to the amount of an electrical short between the contact structure 102 and the sense structure 104.

In various embodiments, the contact arrangement 100 may further include a switch 122. In various embodiments, the switch 122 may be coupled to at least one of the contact structure 102 and the sense structure 104. For example, the switch 122 may be connected to the contact structure 102 at a point 118 and may be connected to the sense structure 104 at a point 120. In various embodiments, the switch 122 may be integrated on a semiconductor substrate. For example, the switch 122 may be integrated on the same semiconductor substrate that the contact structure 102 and the sense structure 104 are arranged on.

In various embodiments, switch 122 may have two, three or four positions. In a first position, for example position “1” of the switch 122 shown in FIG. 1, the sense structure 104 may be connected to the sensing circuit 116. Since the contact structure 102 may also be connected to the sensing circuit 116, a potential difference or a leakage current or a resistance between the contact structure 102 and the sense structure 104 may be measured. The sensing circuit 116 may then provide a corresponding signal at its output 117, which may for example be used to determine if a correct or an incorrect mechanical contacting has taken place or for detecting a potential or latent reliability issue.

In a second position, for example position “2” of the switch 122 shown in FIG. 1, the sense structure 104 may be connected to the contact structure 102. The sense structure 104 may then be at the same potential as the contact structure 102.

In a third position, for example position “3” of the switch 122 shown in FIG. 1, the sense structure 104 may be connected to a predefined potential. For example, the predefined potential may be a ground potential or any other fixed potential.

In a fourth position, for example position “4” of the switch 122 shown in FIG. 1, the sense structure 104 is not connected to any potential. For example, the potential of the sense structure 104 may be floating.

In various embodiments, the switch 122 may have any combination of the first position with the second position, the third position and the fourth position. For example, the switch 122 may have a first position and a second position without a third position and without a fourth position or may have a first position, a third position and a fourth position without a second position.

In various embodiments, switch 122 may be in the first position at times when a detection or measurement is to be performed and be in the second position, third position or fourth position at times during which no detection or measurement is performed.

In various embodiments, the contact arrangement 100 may have a further switch (not shown in FIG. 1) coupled between the contact structure 102 and the sensing circuit 116. The further switch may electrically connect and disconnect the contact structure 116 to the sensing circuit 116.

In various embodiments, the switch 122 and if it is present the further switch may be operated by a control unit (not shown in FIG. 1). In various embodiments, the control unit may operate switch 122 periodically to be in the first position, for example during operation of a circuit arrangement having the contact arrangement 100. In various embodiments, the control unit may operate switch 122 periodically, for example only at one point in time or at certain points in time, to be in the first position. The points in time may for example be during a start-up or during front-end and/or back-end production tests of a circuit arrangement having the contact arrangement 100.

In various embodiments, the control unit may be integrated on or integrated in a semiconductor substrate. For example, the control unit may be integrated on the same semiconductor substrate that the contact structure 102, the sense structure 104 and the switch 122 are arranged on. In various embodiments, the control unit may be part of a build-in-self-test (BIST).

In various embodiments, the sense structure 104 may consist of one or more sense parts. The one or more sense parts may for example be arranged in proximity of a border of the contact structure 102 in a direction in which a misaligned or an impact is to be detected. For example, the closed loop 104 may be separated into four or more separate sense parts, for example a top border part 124, a right border part 126, a bottom border part 128 and a left border part 130. In various embodiments, the sense parts may be arranged around the contact area 102. For example, they may follow a border of the contact structure 102 and may, except for gaps between them, surround the contact structure 102.

In various embodiments, each of the sense parts, for example the border parts 124, 126, 128, 130 may be connected to the sensing circuit 116 as described above. In various embodiments, the sense parts, for example the border parts 124, 126, 128, 130, may be electrically connected in series to each other, for example to form a closed loop or to form an open loop, for example around the contact structure 102, and the resultant structure may be connected to a sensing circuit 116. In various embodiments, each of the sense parts, for example the border parts 124, 126, 128, 130, may be connected to an individual sensing circuit 116.

As an example, the top border part 124 may detect a displacement or an impact in direction A, the right border part 126 may detect a displacement or an impact in direction B, the bottom border part 128 may detect a displacement or impact in direction C and the left border part 130 may detect a displacement or an impact in direction D.

Each of the sense parts, for example the top border part 124, the right border part 126, the bottom border part 128 and the left border part 130 may be used alone. The sense parts do not need to be electrically connected with each other in order to detect a displacement or an impact. For example, only the top border part 124, the right border part 126, the bottom border part 128 and the left border part 130 is sufficient to detect a misalignment or an impact in direction A, in direction B, in direction C and in direction D, respectively.

In various embodiments, the sense parts, for example the border parts 124, 126, 128, 130, may be used in combination with each other. For example, the right border part 126 and the left border part 130 may be used together to detect a displacement or an impact parallel to the directions B, D. Similarly, the top border part 124 and the bottom border part 128 may be used together to detect a displacement or an impact parallel to the directions A, C. However, in various embodiments, the parts may be connected, for example to form a closed loop 104.

A closed loop 104 surrounding the contact structure 102 may be useful as there are no gaps between the sense parts. An incorrect mechanical contacting, such as for example a misalignment or using too high a contact pressure, in a gap might not be detected by the sensing circuit 116. However, if the gap between the sense parts is small enough, for example smaller than the contacting part, an incorrect mechanical contacting may also be detected between the sense parts.

FIG. 1 shows only one closed loop 104. However, in various embodiments, more than one closed loop may be provided. In various embodiments, the plurality of loops may be connected to the sensing circuit 116. In various embodiments, the closed loops may be concentric to each other. In various embodiments, the contact structure 102 may from a centre of the concentric arrangement of the closed loops. In various embodiments, the concentric closed loops may be separated by a gap from each other, that is, they are not in electrical contact with each other. In various embodiments, the gaps are smaller than a contacting part, for example a wire ball or a probe. In other words, the gap may be chosen to be small enough that a contacting part will contact two adjacent closed loops.

In various embodiments, at least two closed loops may be arranged in a same conducting plane. In various embodiments, the closed loops may be coupled to the sensing circuit 116. In various embodiments, the sensing circuit 116 may be configured to determine at least one of an electrical resistance, an electrical current, and an electrical voltage (or potential difference) between the closed loops. In this way, an incorrect mechanical contacting, for example between a first closed loop and a second closed loop may be located by detecting a leakage current, a low resistance or a low potential difference between the first closed loop and the second closed loop.

In various embodiments, a distance of a location, for example of a mechanical contacting, from the contact structure 102 may be specified, for example based on the number of closed loops arranged between the first loop and the contact structure 102. If the distance is known, an adjustment in the mechanical contacting may be corrected faster, for example by using larger adjustment steps.

In various embodiments, the sense parts may also be arranged in a concentric manner, that is, with increasing distance from the contact structure 102, as is described above for closed loops. In various embodiments, the distance of the location of the mechanical contacting from the contact structure 102 may be determined as described above.

The contact structure 102 is shown in FIG. 1 as a rectangle. However, in various embodiments, the contact structure 102 may have any shape. For example, it may be L-shaped or a circle. Similarly, the sense structure 104 or sense parts, for example the border parts 124, 126, 128, 130, may have any shape. In various embodiments, they may have one side that has the same shape as a border of the contact structure 102. For example, if the contact structure 102 is a rectangle, they may have a straight side or edge. For example, if the contact structure 102 is a circle with a first radius, they may have a circular side or edge with a radius larger than the first radius. In various embodiments, they may have one side that has a constant distance from a border of the contact structure 102. In various embodiments, each of the sense parts may be shorter than a width of the corresponding side of the contact pad 102.

FIG. 2 shows an embodiment of a contact arrangement 200. The contact arrangement 200 may be similar to the contact arrangement 100 described in conjunction with FIG. 1 so that all the features described may also apply here. For example, contact arrangement 200 may have a switch 122 even though it is not shown in FIG. 2.

In various embodiments, the sense structure 104 may include at least one open loop surrounding the contact structure 102. In various embodiments, the open loop 104 may be the same and may be arranged in the same manner as the closed loop 104 described in conjunction with contact arrangement 100 except for a gap 210. In various embodiments, the open loop 104 may include a first end 202 and a second end 204. In various embodiments, the first end 202 and a second end 204 may be separated from each other by a gap 210. The gap 210 may be as large as the distance 108 of the open loop 104 from a border 106 of the contact structure 102.

In various embodiments, the first end 202 and the second end 204 may be coupled to a sensing circuit 116. In various embodiments, the first end 202 may have a first connecting point 206 and the second end 204 may have a second connecting point 208. The first connecting point 206 and the second connecting point 208 may be connected to the sensing circuit 116.

In various embodiments, the sensing circuit 116 may be configured to determine at least one of an electrical resistance, an electrical current, and an electrical voltage (or potential difference) between the first end 202 and the second end 204 of the at least one open loop 104.

Measuring the resistance, the current or the voltage may be used to test the integrity of the open loop 104. For example, if the open loop 104 is integer or unimpaired, no resistance or a very low resistance may be present between the first end 202 and the second end 204 as they are shorted. Similarly, if the open loop 104 is integer or unimpaired, no potential difference or a very low potential difference may be measured between the first end 202 and the second end 204. Similarly, if the open loop 104 is integer or unimpaired, a current may flow between the first end 202 and the second end 204 and may be measured. If it is determined that the open loop is integer or unimpaired, it may be assumed that the contact structure 102 was correctly mechanical contacted.

Conversely, measuring the resistance, the current or the voltage may be used to test if the open loop 104 has been impacted by the mechanical contacting. For example, incorrectly mechanically contacting the contact structure 102, for example by a misaligned probe, may damage the open loop 104, for example by scratching it. In various embodiments, the resistance and the potential difference between the first end 202 and the second end 204 may be higher and a current flowing between the first end 202 and the second end 204 may be lower than for a correct mechanical contacting. The amount of resistance may indicate the amount of damage. A higher resistance may indicate a larger damage that a lower resistance.

In various embodiments, the measurement between the first end 202 and the second end 204 may be combined with the measurement of at least one of an electrical resistance, an electrical current, and an electrical voltage (or potential difference) between the sense structure 104 and the contact structure 102 as described in conjunction with contact arrangement 100.

While FIG. 2 shows an open loop 104, which except for the gap 210 surrounds all of the contact structure 102, the sense structure 104 may in various embodiments also consist of one or more of the sense parts 104 as described in conjunction with contact arrangement 100. For example, the sense part 104 may be right border part 126. In various embodiments, the one or more of the sense parts may have a respective first end 202 and a respective second end 204. The respective first end 202 and the respective second end 204 may for example be located at opposite ends of the respective sense part. In this case, nearly all of the length of the sense parts may be used for the detecting an impact. The respective first end 202 and the respective second end 204 may be coupled to the sensing circuit 116 which may be configured to determine at least one of an electrical resistance, an electrical current, and an electrical voltage (or potential difference) between the first end 202 and the second end 204 of the respective sense part. Using more than one sense part for the sense structure 104 may help to detect the direction and extend in which an impact occurred, as is described above. In various embodiments, the measurement between the respective first end 202 and the respective second end 204 may be combined with the measurement of at least one of a respective electrical resistance, a respective electrical current, and a respective electrical voltage (or potential difference) between the respective sense part 104 and the contact structure 102 as described above.

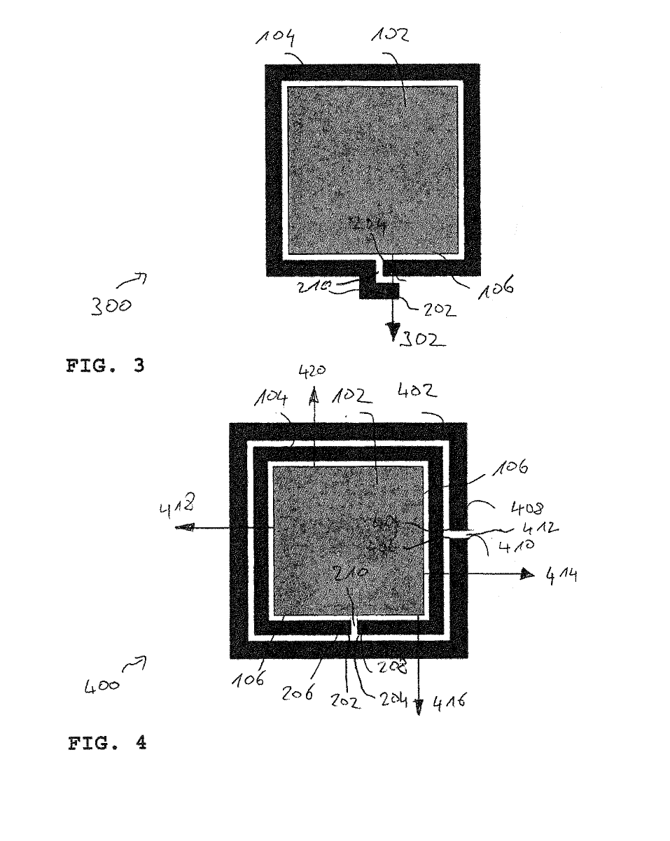

FIG. 3 shows an embodiment of a contact arrangement 300. The contact arrangement 300 may be similar to the contact arrangement 200 described in conjunction with FIG. 2 so that all the features described may also apply here.

As can been seen in FIG. 2, the open loop 104 may have a gap 210. In various embodiments, the gap 210 may be a blind spot when detecting an impact. In other words, it is possible that an impact, such as a scratch through gap 210, will not be detected.

In various embodiments, the first end 202 and the second end 204 may overlap in a direction 302 orthogonal to a border 106 of the contact structure 102. The effect of the overlapping may be similar to the effect of the closed loop 104 of contact arrangement 100. In other words, it is more likely that an impact is detected. For example, in FIG. 3, a scratch through the gap 210 from the contact structure 102 in direction 302 may damage some part of the sense structure 104 located before the first end 202 and may be detected. Compared to a closed loop, the overlapping open loop 104 may allow the determination of at least one of an electrical resistance, an electrical current, and an electrical voltage (or potential difference) between the first end 202 and the second end 204 of the respective sense part 104 so that the integrity of the sense structure 104 may be determined.

In various embodiments, the measurement between the first end 202 and the second end 204 may be combined with the measurement of at least one of an electrical resistance, a respective electrical current, and a respective electrical voltage between the overlapping open loop 104 and the contact structure 102 as described above.

FIG. 4 shows an embodiment of a contact arrangement 400. The contact arrangement 400 may be similar to the contact arrangement 200 described in conjunction with FIG. 2 so that all the features described may also apply here.

As can been seen in FIG. 2, the open loop 104 may have a gap 210 which may be a blind spot when detecting an impact, such as is described above.

In various embodiments, the contact arrangement 400 may include a first open loop 104 and a second open loop 402. The first open loop 104 may have a first end 202 and a second end 204. The second open loop 402 a first end 404 and a second end 406.

The first end 202 and the second end 204 of the first open loop 104 may have a respective connecting point 206, 208. The first end 404 and the second end 406 of the second open loop 402 may have a respective connecting point 408, 410. The connecting points 206, 208, 408, 410 may be connected to the sensing circuit 116.

In various embodiments, a first gap 210 may be formed between the first end 202 and the second end 204 of the first open loop 104. In various embodiments, a second gap 412 may be formed between the first end 408 and the second end 410 of the second open loop 402. In various embodiments, the first gap 210 and the second gap 412 do not overlap in a direction 414, 416, 418, 420 orthogonal to a border 106 of the contact structure 102. The effect of the non-overlapping may be similar to the effect of the closed loop 104 of contact arrangement 100. In other words, it is more likely that an impact is detected. For example, in FIG. 4, a scratch through the gap 210 from the contact structure 102 in direction 416 may damage some part of the second loop 402 and may be detected. Compared to a closed loop, the two open loops 104, 402 may each allow the respective determination of at least one of an electrical resistance, an electrical current, and an electrical voltage (or potential difference) between the respective first end 202, 404 and the respective second end 204, 406 so that the integrity of the first open loop 104 and the second open loop 402 may be determined.

In various embodiments, the measurement between the respective first end 202, 404 and the respective second end 204, 406 may be combined with a respective measurement of at least one of a resistance, an electrical current, and an electrical voltage (or potential difference) between at least two of the first open loop 104, the second open loop 402 and the contact structure 102. For example, a first leakage current may be determined between the first open loop 104 and the contact structure 102. For example, a second leakage current may be determined between the second open loop 402 and the contact structure 102. For example, a third leakage current may be determined between the first open loop 104 and the second open loop 402.

In various embodiments, the different leakage currents may be used to determine the severity of impact of the mechanical contacting. For example, the first leakage current may be used to issue a warning that the wire bonding or probing is misaligned and needs adjustment. For example, the second leakage current or the third leakage current may be used to indicate a failure. In various embodiments, the severity may increase with an increase in distance of the sense structure, for example of an open loop 104, 402, from the contact structure 102.

In various embodiments, the first open loop 104 and the second open loop 402 may be arranged in a same conducting plane. In various embodiments, the contact structure 102 may be arranged in the same conducting plane as the first open loop 104 and the second open loop 402.

While FIG. 4 shows only two open loops 104, 402, any number of loops may be used. In various embodiments, the loops may be arranged concentrically to the contact structure 102.

Instead of non-overlapping gaps of open loops, the principle of non-overlapping gaps in a direction orthogonal to a border of the contact structure 102 may also be applied to two or more sense parts as described in conjunction with contact arrangement 100.

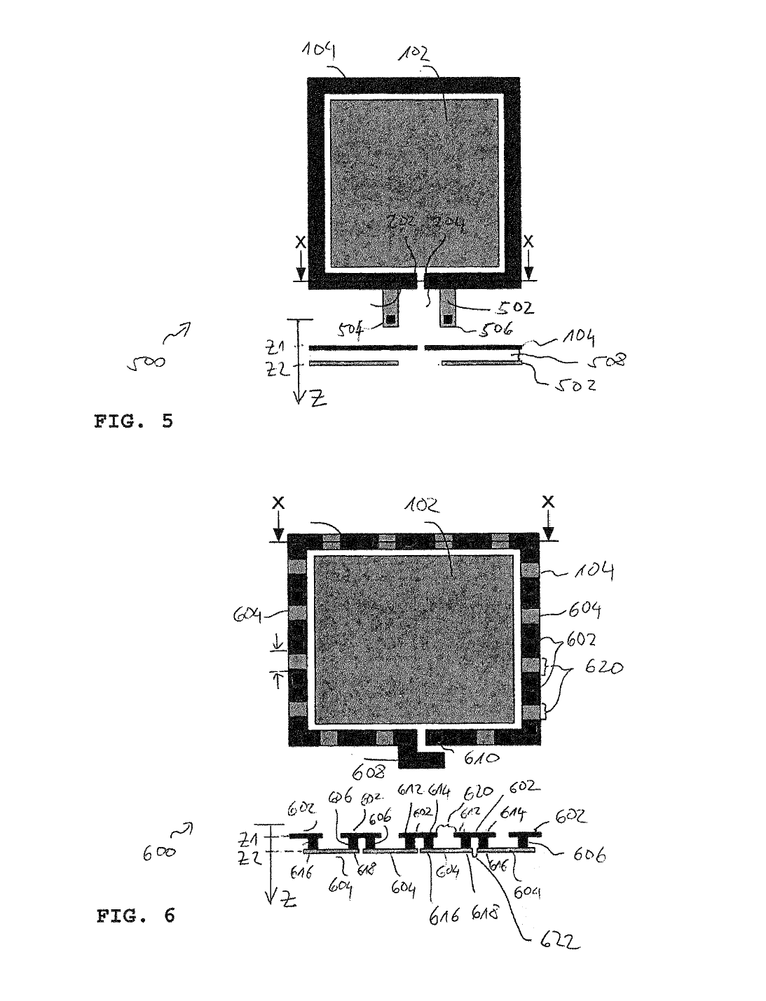

FIG. 5 shows an embodiment of a contact arrangement 500. A cross section along X-X is shown at the bottom of the figure. The contact arrangement 500 may be similar to the contact arrangement 400 described in conjunction with FIG. 4 so that all the features described may also apply here.

In various embodiments, a first open loop 104 and a second open loop 502 are arranged in different conducting planes. For example, the first open loop 104 may be in a plane with a first Z-coordinate Z1 and the second open loop 502 may be in a plane with a another Z-coordinate Z2. The Z-direction may be a direction that is perpendicular or orthogonal to a plane of the contact structure 102.

In various embodiments, the layers in which the first open loop 104 and the second open loop 502 are arranged in may be metal layers, electrically conducting (doped) polysilicon (poly-Si) layers or electrically conducting diffusion regions. The electrically conducting polysilicon and the diffusion regions may be semiconductors with high levels of doping that act more like metals than semiconductors (degenerate semiconductor). The first open loop 104 may for example be in a metal layer, for example in a top metal layer.

In various embodiments, the first open loop 104 and the second open loop 502 may overlap each other in a direction perpendicular to a plane of the contact structure 102. For example, the first open loop 104 and the second open loop 502 may overlap each other in the Z-direction. As a result, some parts of the first open loop 104 may cover up some parts of the second open loop 502 as can be seen in the top part of FIG. 5.

In various embodiments, the contact structure 102 may be arranged in the same conducting plane as one of the first open loop 104 or the second open loop 502. In other words, the contact structure 102 and one of the first open loop 104 and the second open loop 502 may have the same Z-coordinate. For example, the first open loop 104 and the contact structure 102 may be in the same top metal layer.

In various embodiments, an isolation layer 508 may be arranged between the first open loop 104 and the second open loop 502. The isolation layer 508 may for example include silicon dioxide SiO₂.

In various embodiments, the contact structure 102, the first open loop 104, the isolation layer 508 and the second open loop 502 may be arranged on a semiconductor substrate. In various embodiments, the second open loop 502 may be closer to the substrate than the first open loop substrate 104.

In various embodiments, the sensing circuit 116 may be coupled to at least one of the contact structure 102, the first open loop 104 and the second open loop 502. In various embodiments, the first open loop 104 may have a first end 202 and a second end 204, which may be coupled to the sensing circuit 116. In various embodiments, the second open loop 502 may have a first end 504 and a second end 506, which may be coupled to the sensing circuit 116.

In various embodiments, the sensing circuit 116 may be configured to determine at least one of an electrical resistance, an electrical current and an electrical voltage (or potential difference) between at least one of the first end 202 and the second end 204 of the first open loop 104 and the first end 504 and the second end 506 of the second open loop 502. The resistance, the current or the voltage may indicate that there has been an impact due to incorrect mechanical contacting on the first open loop 104 or the second open loop 502 which may act as sense structures. For example, the first open loop 104 or the second open loop 502 may have been damaged during the mechanical contacting. They may for example have been scratched by a probe, for example during testing, so that the resistance between the first end 202, 504 and the second end 204, 506 may have increased.

In various embodiments, the sensing circuit 116 may be configured to determine at least one of an electrical resistance, an electrical current, and an electrical voltage (or potential difference) between at least one of the first open loop 104 and the contact structure 102, the second open loop 502 and the contact structure 102, and the first open loop 104 and the second open loop 502. The resistance, the current or the voltage may indicate that there has been an impact due to incorrect mechanical contacting. For example, a decrease of the resistance or the voltage between the first open loop 104 and the contact structure 102 may indicate a misaligned wire bond where the wire bond overlaps the first open loop 104 and the contact structure 102. For example, a decrease of the resistance or voltage between the first open loop 104 and the second open loop 502 may indicate that the isolation layer 508 between the first open loop 104 and the second open loop 502 has been damaged, for example by a mechanical contacting with a contacting force that is too large, so that the first open loop 104 and the second open loop 502 are in touch with each other.

While only two open loops are shown in FIG. 5, there may be any number of open loop arranged at different Z-coordinates. Further, the contact arrangement 500 may also be combined with the teachings of contact arrangement 400. For example, there may be more than one loop in one layer and the loops may be concentric to the contact structure 102.

FIG. 6 shows an embodiment of a contact arrangement 600. A cross section along X-X is shown at the bottom of the figure. The contact arrangement 600 may be similar to the contact arrangement 500 described in conjunction with FIG. 5 so that all the features described may also apply here.

In various embodiments, the sense structure 104 may include at least one sense part 602 in a first conducting plane, at least one sense part 604 in a second conducting plane and at least one electrically conducting element 606 electrically connecting a respective sense part 602 in the first conducting plane to a respective sense part 604 in the second conducting plane.

In various embodiments, the first conducting plane may be in a plane with a first Z-coordinate Z1 and the second conducting plane may be in a plane with another Z-coordinate Z2. The Z-direction may be a direction that is perpendicular or orthogonal to a plane of the contact structure 102. In various embodiments, the first and second conducting planes may be metal layers, electrically conducting (doped) polysilicon (poly-Si) layers or electrically conducting diffusion regions. The electrically conducting polysilicon and the diffusion regions may be semiconductors with high levels of doping that act more like metals than semiconductors (degenerate semiconductor). The first conducting plane may for example be a metal layer, for example a top metal layer. In various embodiments, the contact structure 102 may be arranged in the same conducting plane as the first conducting plane. In other words, the contact structure 102 and first conducting plane may have the same Z-coordinate. For example, the first conducting plane and the contact structure 102 may be in the same top metal layer.

In various embodiments, the sense parts 602 of the first conducting plane may be arranged around the contact structure 102, as is shown on FIG. 6. For example, they may be arranged along a border of the contact structure 102, for example at a given distance from the border, as described above.

In various embodiments, adjacent sense parts 602 of the first conducting plane may have a gap 620 or a distance between them. In other words, they are not in direct electrical contact with each other. In various embodiments, adjacent sense parts 604 of the second conducting plane may have a gap 622 or a distance between them. In other words, they are not in direct electrical contact with each other.

In various embodiments, sense parts 602 of the first conducting plane and sense parts 604 of the second conducting plane may overlap each other partially in a direction perpendicular to a plane of the contact structure 102, for example in the Z-direction.

In various embodiments, a respective sense part 604 of the second conducting plane may be arranged below a respective gap 620 between adjacent sense parts 602 of the first conducting plane.

In various embodiments, an electrically conducting element 606 may be arranged between the overlap of a sense part 602 of the first conducting plane and a sense part 604 of the second conducting plane. It may electrically connect a sense part 602 of the first conducting plane and a sense part 604 of the second conducting plane. In various embodiments, the electrically conducting element 606 may be a via.

In various embodiments, sense parts 602 of the first conducting plane may have a respective first end 612 and a respective second end 614 and sense parts 604 of the second conducting plane may have a respective first end 616 and a respective second end 618.

In various embodiments, the second end 614 of a first sense part 602 of the first conducting plane may be connected via an electrically conducting element 606 to the first end 616 of a sense part 604 of the second conducting plane and the first end 612 of a second sense part 602 of the first conducting plane may be connected via another electrically conducting element 606 to the second end 618 of the sense part 604 of the second conducting plane. The second end 618 of a first sense part 604 of the second conducting plane may be connected via an electrically conducting element 606 to the first end 612 of a sense part 602 of the first conducting plane and the first end 616 of a second sense part 604 of the second conducting plane may be connected via another electrically conducting element 606 to the second end 614 of the sense part 602 of the first conducting plane. In this manner, the sense parts 602 of the first conducting plane and the sense parts 604 of the second conducting plane may be electrically connected in series to each other. For example, they may form a closed loop or to form an open loop as a sense structure 104 as was described above, where the sense parts of the loop are arranged in an alternating manner in the first conducting plane and the second conducting plane.

All the measurements of the contacts arrangements discussed in conjunction with FIGS. 1 to 5 may be applied to contact arrangement 600. In various embodiments, the loop may have overlapping first end 608 and second end 610, there may be more than one concentric loop arranged around the contact area 102 and there may be more than two conduction layers with sense parts at more than two Z-coordinates. While the sense parts 602, 604 and the contact area 102 are shown rectangular, they may have any shape, as described above.

In various embodiments, the electrically conducting elements 606 may be configured as predetermined mechanical breaking points of the sense structure 104. In other words, the electrically conducting element 606 may represent mechanically weak parts compared to other parts of the contact arrangement 600. In various embodiments, the electrically conducting elements 606 may be made from a harder or more brittle material than the other parts. In various embodiments, if a force parallel or orthogonal to the plane of the contact structure 102 is applied on the sense parts 602 of the first conducting layer, the electrically conducting elements 606 would break before other parts break causing an electrical interruption in the loop. The force may for example occur during an incorrect mechanical contacting, for example if a wire bond or a probe is misaligned or too high a contacting force is used, as is described above.

In various embodiments, the sensing circuit 116 may be coupled to a first end 608 and a second end 610 of the loop to detect an interruption of the loop. In various embodiments, the sensing circuit 116 may be configured to determine at least one of an electrical resistance, an electrical current and an electrical voltage (or potential difference) between at least one of the first end 608 and the second end 610 of the loop 104 and between the loop 104 and the contact structure 102. The resistance, the current or the voltage may indicate that there has been an impact due to incorrect mechanical contacting.

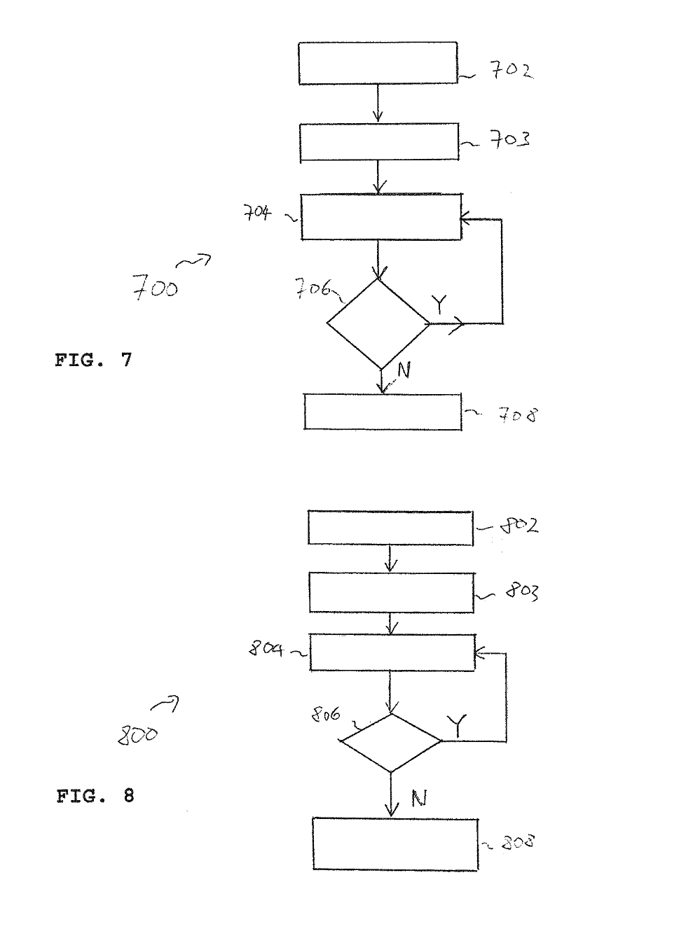

FIG. 7 shows an embodiment of a method 700. In various embodiments, the method may be used for detecting an incorrect mechanical contacting of a contact structure. An incorrect mechanical contacting may for example be a misaligned mechanical contacting or a mechanical contacting with too high a contacting force.

In various embodiments, the method 700 may include step 702 of arranging at least one sense structure in proximity of the contact structure such that an incorrect mechanical contacting of the contact structure will impact the sense structure and a correct mechanical contacting of the contact structure will not impact the sense structure.

In various embodiments, the method 700 may include step 703 of mechanical contacting the contact structure. In various embodiments, the mechanical contacting may be a contacting using a contacting part, such as a test probe, or a wire bond.

In various embodiments, the method 700 may include step 704 of measuring or determining at least one of an electric voltage between the contact structure and the sense structure, an electric current flowing between the contact structure and the sense structure, a resistance between the contact structure and the sense structure, and a resistance of the sense structure after mechanically contacting the contact structure.

In various embodiments, the method 700 may include step 706 of comparing at least one of the measured or determined voltage, current and resistance with a corresponding limit or threshold.

In various embodiments, if the measured or determined voltage, current and resistance exceeds a respective limit or threshold, the method may continue with step 708. In step 708, a signal may be output, indicating that the respective limit or threshold has been exceeded. In various embodiments, the signal may indicate that an incorrect mechanical contacting has taken place. For example, it may indicate that a probe or a wire bond has been misaligned or misplaced, or that too high a force was used in mechanically contacting the contact structure, or that the sense structure was damaged in some way or other. In various embodiments, the measurement may be performed during the production of a contact arrangement.

In various embodiments, if the measured or determined voltage, current and resistance does not exceed or is below the respective limit or threshold, the flow may return to step 704 and continue with measuring or determining at least one of a voltage, a current and a resistance. In various embodiments, the measurement may be performed during the operation of a contact arrangement. For example, the measurement may be performed continuously, periodically, for example as part of a build in self test, or aperiodically, for example during start-up of a circuit having a contact arrangement.

In various embodiments, the signal may also indicate changes in the contact arrangement that may have occurred over time. For example, such a change may occur due to aging processes, corrosion or mechanical stresses. For example, an aging process may be due to temperature or humidity extremes or due to a number of temperature or humidity cycles.

In various embodiments, the method 700 may stop with step 708.

In various embodiments, during times at which no measurement is performed, the sense structure may be connected to a predefined potential or the contact structure. For example, the sense structure may be connected to the predefined potential or the contact structure by means of a switch such as described above.

FIG. 8 shows an embodiment of a method 800. In various embodiments, the method may be used for detecting a misalignment of a wire bond with respect to a bond pad.

In various embodiments, the method 800 may include step 802 of arranging at least one conducting sense structure in proximity of the bond pad such that a misaligned wire bond will contact both the sense structure and the bond pad.

In various embodiments, the method 800 may include step 803 of wire bonding the bond pad. In various embodiments, wire bonding may be a ball bond or a wedge bond.

In various embodiments, the method 800 may include step 804 of measuring or determining at least one of an electric voltage between the bond pad and the sense structure, an electric current flowing between the bond pad and the sense structure; and a resistance between the bond pad and the sense structure.

In various embodiments, the method 800 may include step 806 of comparing at least one of the measured or determined voltage, current and resistance with a respective limit or threshold.

In various embodiments, if the measured or determined voltage, current and resistance exceeds the respective limit or threshold, the method may continue with step 808. In step 808, a signal may be output, indicating that the limit or threshold has been exceeded. In various embodiments, the signal may indicate that the wire bond was misaligned or misplaced, for example with respect to the bond pad.

In various embodiments, the signal may indicate changes in the wire bond that may have occurred over time. For example, such a change may occur due to aging processes, corrosion or mechanical stresses. For example, an aging process may be due to temperature or humidity extremes or due to a number of temperature or humidity cycles.

In various embodiments, if the measured or determined voltage, current and resistance is does not exceed or is below the respective limit or threshold, the flow may return to step 804 and continue with measuring or determining at least one of a voltage, a current and a resistance. In various embodiments, the measurement may be performed during the operation of a contact arrangement. For example, the measurement may be performed continuously, periodically, for example as part of a build in self test, or aperiodically, for example during start-up of a circuit having the bond pad and bond wire.

In various embodiments, the method may stop with step 808.

In various embodiments, during times at which no measurement is performed, the sense structure may be connected to a predefined potential or the bond pad. For example, the sense structure may be connected to the predefined potential or the bond pad by means of a switch such as described above.

In various embodiments, the methods 700, 800 may be performed using any of the contact arrangements 100, 200, 300, 400, 500, 600 described above. In various embodiments, the contact arrangements 100, 200, 300, 400, 500, 600 may be operated by the methods 700, 800.

The embodiments of the contact arrangements 100, 200, 300, 400, 500, 600 and the corresponding FIGS. 1 to 6 show only one contact structure 102. However, in various embodiments, there may be more than one contact structure 102, for example when the contact structure 102 includes a plurality of contact parts, and the methods 700, 800 may be applied to a plurality of contact parts. A contact part may have some or all of the features of the contact structure 102 described above.

In various embodiments, the sense structure 104 may surround the plurality of contact parts. For example, the sense structure 102 may be a closed loop or an open loop or a plurality of sense parts which surround the plurality of contact parts.

In various embodiments, some or all of the contact parts may have a respective sense structure 104, that is, a respective sense structure may be arranged in proximity of a respective contact part and configured such that a correct mechanical contacting of the respective contact part will not impact the respective sense structure and an incorrect mechanical contacting of the respective contact part will impact the respective sense structure. In other words, there may be a plurality of contact arrangements.

In various embodiments, the plurality of contact parts and the sense structure or the respective sense structures 104 may be connected to a sensing circuit 116 like the contact structure and the sense structure or sense parts described above. As a first example, some or all of the respective sense structures or sense parts 104 may be connected in series with each other. A first and a last of the respective sense structures connected in series may be connected to the sensing circuit 116. As a second example, some or all of the respective sense structures 104 and their respective contact parts may be connected to their own or respective sensing circuit 116. As a third example, some or all of the respective sense structures 104 and their respective contact parts may be connected to a multiplexer and be multiplexed to the sensing circuit 116. The multiplexer may be operated by the control unit. In various embodiments, the respective sense structures and their respective contact parts may be connected to the sensing circuit 116 in a combination of at least one of the first example, the second example and the third example.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A contact arrangement, comprising:
a contact structure;
a sense structure arranged in proximity of the contact structure and configured such that
a correct mechanical contacting of the contact structure will not impact the sense structure; and
an incorrect mechanical contacting of the contact structure will impact the sense structure.

2. The contact arrangement of claim 1, further comprising:
a sensing circuit coupled to at least the sense structure and configured to detect the impact on the sense structure.

3. The contact arrangement of claim 2,
wherein the contact structure is electrically conducting and is coupled to the sensing circuit; and
the sense structure comprises at least one electronically conducting portion arranged in proximity of a border of the contact structure.

4. The contact arrangement of claim 3,
wherein the contact structure is a bond pad.

5. The contact arrangement of claim 1,
wherein the contact structure and the sense structure are arranged in a same conducting layer.

6. The contact arrangement of claim 5,
wherein the contact structure and the sense structure comprise a same kind of surface.

7. The contact arrangement of claim 1,
wherein the sense structure is formed in one of
a metal layer;
a electrically conducting polysilicon layer; and
an electrically conducting diffusion region.

8. The contact arrangement of claim 2,
wherein the sensing circuit is configured to determine at least one of
an electrical resistance;
an electrical current; and
an electrical voltage
between the sense structure and the contact structure.

9. The contact arrangement of claim 2,
wherein the sense structure comprises at least one closed loop surrounding the contact structure.

10. The contact arrangement of claim 2,
wherein the sense structure comprises at least one open loop surrounding the contact structure; and
wherein a first end and a second end of the at least one open loop are coupled to the sensing circuit.

11. The contact arrangement of claim 10,
wherein the sensing circuit is configured to determine at least one of
an electrical resistance;
an electrical current; and
an electrical voltage
between the first end and the second end of the at least one open loop.

12. The contact arrangement of claim 10,
wherein the first end and the second end overlap in a direction orthogonal to a border of the contact structure.

13. The contact arrangement of claim 10,
wherein a first gap formed between a first end and a second end of a first open loop of the at least one open loop and a second gap formed between a first end and a second end of a second open loop of the at least one open loop do not overlap in a direction orthogonal to a border of the contact structure.

14. The contact arrangement of claim 13,
wherein the first open loop and the second open loop are arranged in a same conducting plane.

15. The contact arrangement of claim 13,
wherein the contact structure is arranged in the same conducting plane as the first open loop and the second open loop.

16. The contact arrangement of claim 10,
wherein a first open loop of the at least one open loop and a second open loop of the at least one open loop are arranged in different conducting planes.

17. The contact arrangement of claim 16,
wherein the contact structure is arranged in the same conducting plane as one of the first open loop or the second open loop.

18. The contact arrangement of claim 16,
wherein the first open loop and the second open loop overlap each other in a direction perpendicular to a plane of the contact structure.

19. The contact arrangement of claim 10,
wherein the sensing circuit is configured to determine at least one of
an electrical resistance;
an electrical current; and
an electrical voltage
between at least one of
the first open loop and the contact structure;
the second open loop and the contact structure, and
the first open loop and the second open loop.

20. The contact arrangement of claim 13,
wherein the first end and the second end of the first open loop and the first end and the second end of the second open loop are coupled to the sensing circuit.

21. The contact arrangement of claim 1,
wherein the sense structure comprises:
at least one sense part in a first conducting plane;
at least one sense part in a second conducting plane; and
at least one electrically conducting element configured to electrically connect a sense part in the first conducting plane to a sense part in the second conducting plane,
wherein the at least one electrically conducting element is configured as a predetermined mechanical breaking point of the sense structure.

22. The contact arrangement of claim 2, further comprising:
a switch configured to connect the sense structure to at least one of:
the sensing circuit;
the contact structure; and
a fixed potential.

23. The contact arrangement of claim 1, wherein
the contact structure and the sense structure are arranged on one of
a semiconductor substrate; and
a printed circuit board.

24. The contact arrangement of claim 1, wherein
the contact structure comprises a plurality of contact parts.

25. The contact arrangement of claim 24, wherein
wherein a respective sense structure is arranged in proximity of a respective contact part and configured such that
a correct mechanical contacting of the respective contact part will not impact the respective sense structure; and
an incorrect mechanical contacting of the respective contact part will impact the respective sense structure.

26. A method for detecting an incorrect mechanical contacting of a contact structure, comprising:
arranging at least one sense structure in proximity of the contact structure such that an incorrect mechanical contacting of the contact structure will impact the sense structure and a correct mechanical contacting of the contact structure will not impact the sense structure;
mechanical contacting the contact structure; and
measuring at least one of
an electric voltage between the contact structure and the sense structure;
an electric current flowing between the contact structure and the sense structure;
a resistance between the contact structure and the sense structure; and
a resistance of the sense structure.

27. The method of claim 26,
wherein the measuring is performed during a production of a contact arrangement.

28. The method of claim 26,
wherein the measuring is performed during an operation of a contact arrangement.

29. The method of claim 26,
wherein, during times of no measuring the sense structure is connected to one of the following:
a predefined potential; and
the contact structure.

30. A method for detecting a misalignment of a wire bond with respect to a bond pad, comprising:
arranging at least one conducting sense structure in proximity of the bond pad such that a misaligned wire bond will contact both the sense structure and the bond pad and an aligned wire bond will not contact the sense structure;
wire bonding the bond pad; and
measuring at least one of
an electric voltage between the bond pad and the sense structure;
an electric current flowing between the bond pad and the sense structure; and
a resistance between the bond pad and the sense structure.
